(19) United States
(12) Patent Application Publication
(10) Pub. No.: US 2001/0009504 A1
(43) Pub. Date: Jul. 26, 2001

(54) One system module

(76) Inventors: Jae-Choon Lee, Seoul (KR); Min-Kyu Hwang, Kwangmyung (KR)

Correspondence Address: BIRCH STEWART KOLASCH & BIRCH, PO BOX 747, FALLS CHURCH, VA, 22040-0747, US

(21) Appl. No.: 09/764,208

(22) Filed: Jan. 19, 2001

(30) Foreign Application Priority Data
Jan. 20, 2000 (KR) 2634/2000

(51) Int. Cl. H05K 7/00

(52) U.S. Cl. 361/729

(57) ABSTRACT

A one system module in which a ceramic PCB and an epoxy PCB are disposed inside a module body and a power element and a signal element are respectively mounted at the upper portion of each PCB, wherein a groove is made at the lower side surface and at the middle side surface of the module body to support the ceramic PCB and the epoxy PCB formed in a two-story structure, and a power pin for receiving a power signal from an external source is mounted on the ceramic PCB and a signal pin for receiving various signals from an external source is mounted on the epoxy PCB. With this one system module, the ceramic PCB and the epoxy PCB can be firmly supported by the groove made on the module body. And, since the power pin and the signal pin are separately disposed on the two PCBs, use of the socket is reduced, so that the area utility of the PCB is increased as well as acquiring a compact module.

### BACKGROUND OF THE INVENTION

1. Field of the Invention

The present invention relates to a one system module structure in which a groove is made on a module body on which a ceramic PCB(Printed Circuit Board) and an epoxy PCB are firmly mounted, and more particularly to a one system module structure in which a power pin is mounted on a ceramic PCB and a signal pin is mounted on an epoxy PCB to increase an area utility of the PCB and construct a compact module.

2. Description of the Background Art

A one system module has such a structure that a PCB on which components are inserted or mounted and a component such as an SMD (Surface Mounted Device) are integrated on a single module.

FIG. 1 illustrates a structure of one system module in accordance with a conventional art.

As shown in the drawing, a groove is made at a lower portion of a module body 10, on which a ceramic PCB 11 is fixed. An epoxy PCB 12 is disposed on the upper surface of the ceramic PCB 11. A socket 13 for signal transmission is disposed between the ceramic PCB 11 and the epoxy PCB 12.

Pins for receiving a power signal and various signals from an external source are mounted on an upper portion of the PCB 11. Also, power elements (i.e., BD&Tr, HVIC, IGBT & FWD (Free Wheeling Diode), etc.) are mounted on the PCB 11 by wire-bonding.

A microcomputer device and its peripheral devices are mounted on the upper part of the epoxy PCB 12 by wire-bonding.

A heat-hardened resin is coated in a gel state to protect the wire-bonding for the internal PCBs 11 and 12 of the module body 10 and elements and a cover 15 is mounted to cover the entire module.

The one system module of the conventional art constructed as described above will now be explained.

With reference to FIG. 1, first, a groove is made at a lower part at the side of the module body 10, and the ceramic PCB 11 is inserted to be fixes in the groove. The module body 10 is a case made of a hard molding heat-hardened resin.

The ceramic PCB 11 has a characteristic of a good heat transfer rate, so that power elements, such as a bridge diode, a power transistor, a power element, a free wheeling diode or a high voltage IC (HVIC) for driving such elements are mounted thereon.

Generally, the one system module has a structure of two-storied PCBs for integration, of which the ceramic PCB 11 having a favorable heat transfer is disposed at the lower part while the inexpensive epoxy PCB 12 is disposed at the upper part thereof.

On the epoxy PCB 12, a microcomputer device, that is, a non-heating component, peripheral components and other components are mounted.

The ceramic PCB 11 disposed at the lower part and the epoxy PCB 12 disposed at the upper part are electrically connected by means of the socket 13.

Signal flow in this structure will now be described.

When power is supplied and the microcomputer generates a command, the command is transferred through the socket 13 to the high voltage IC (HVIC) mounted on the ceramic PCB, according to which the high voltage IC (HVIC) drives the power element (IGBT: Insulated gate bipolar transistor) so that a motor (not shown) is driven.

As for the elements to be mounted on the ceramic PCB 11 and on the epoxy PCB 12, a bare-type components are used for a compact design.

In order to connect the bare-type components, wire-bonding is used. In this respect, the elements (BD&Tr, HVIC, IGBT, FWD) mounted on the ceramic PCB 11 are connected by aluminum wire bonding, while the microcomputer mounted on the epoxy PCB 12 is connected by a gold wire bonding.

A power pin for receiving power and various signals from an external source and a signal pin are mounted on the ceramic PCB 11. The power pin and the signal pin are successively arranged.

The pins are inserted into a molding heat-hardened resin of the module and then mounted on the ceramic PCB by lead.

In order to protect the wire-bonding for mounting the components on the internal PCBs of the module body 10 and the components mounted by the wire-bonding, the ‘B’ part is coated with a heat-hardened resin in a gel state, of which the upper part is covered by a cover 15.

FIG. 2 is a schematic circuit diagram of a power board mounted on the ceramic PCB of FIG. 1 in accordance with the conventional art.

As shown in the drawing, as a principal components, six IGBTs and six FWDs are mounted in a bare type, and three gate drives are mounted to drive the IGBTs

The power board includes an element which has a function of preventing over-current flowing to the IGBT and over-temperature.

The power board also includes a rectifier, a driving source for driving elements, and a switching mode power supply (SMPS).

The rectifier converts an AC220V to a DC310V. The rectifier converts an AC to a DC through a bridge diode. A voluminous electrolytic condenser is disposed at an outer side of the module.

The SMPS serves to supply power of each component with the DC obtained after being converted by the rectifier.

FIG. 3 illustrates a signal board mounted on the epoxy PCB 12 in the module body 10.

The signal board includes a microcomputer device required to drive the IGBT mounted on the ceramic PCB 11, a bootstrap circuit, a load driving unit and a microcomputer peripheral circuit.

However, the above-described conventional art, in which the socket is used to connect the ceramic PCB and the epoxy PCB and the pins (the power pin and the signal pin) are disposed on the ceramic PCB, has problems that, if the ceramic PCB and the epoxy PCB are not firmly supported, a poor contact occurs, shortening the durability due to variation of the product. In addition, because of the use of the socket, the usable space of the PCB is reduced, running counter a compact module.

### SUMMARY OF THE INVENTION

Therefore, an object of the present invention is to provide a one system module structure in which a module body is grooved on which a ceramic PCB and an epoxy PCB are firmly mounted.

Another object of the present invention is to provide a one system module structure in which a power pin is mounted on a ceramic PCB and a signal pin is mounted on an epoxy PCB to reduce using of socket, thereby increasing area utility of the PCB and obtaining a compact module.

Still another object of the present invention is to provide a one system module structure in which various signals are immediately processed by a signal pin mounted on an epoxy PCB, thereby increasing module utility in case that a module is applied afterwards.

To achieve these and other advantages and in accordance with the purpose of the present invention, as embodied and broadly described herein, there is provided a one system module in which a ceramic PCB and an epoxy PCB are disposed inside a module body and a power element and signal elements are respectively mounted at the upper portion of each PCB, wherein a groove is made at the lower side surface and at the middle side surface of the module body to support the ceramic PCB and the epoxy PCB formed in a two-story structure, and a power pin for receiving a power signal from an external source is mounted on the ceramic PCB and a signal pin for receiving various signals from an external source is mounted on the epoxy PCB.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a structure of a one system module in accordance with a conventional art;

FIG. 2 is a schematic circuit diagram of power elements mounted on a ceramic PCB of the one system module of FIG. 1 in accordance with the conventional art;

FIG. 3 is a schematic circuit diagram of signal elements mounted on an epoxy PCB of the one system module of FIG. 1 in accordance with the conventional art; and

FIG. 4 shows a structure of one system module in accordance with the present invention.

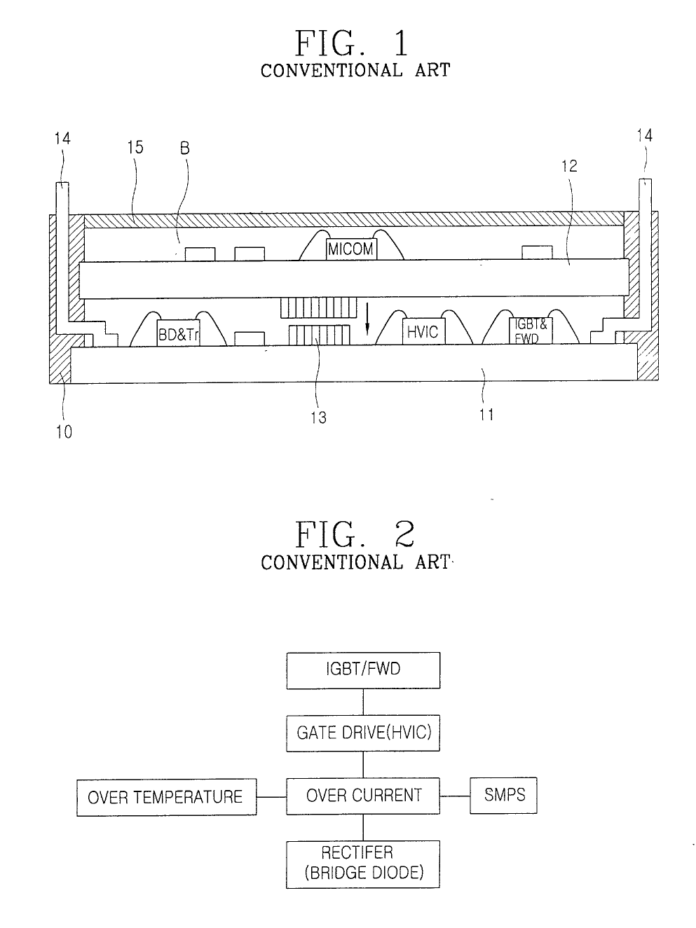

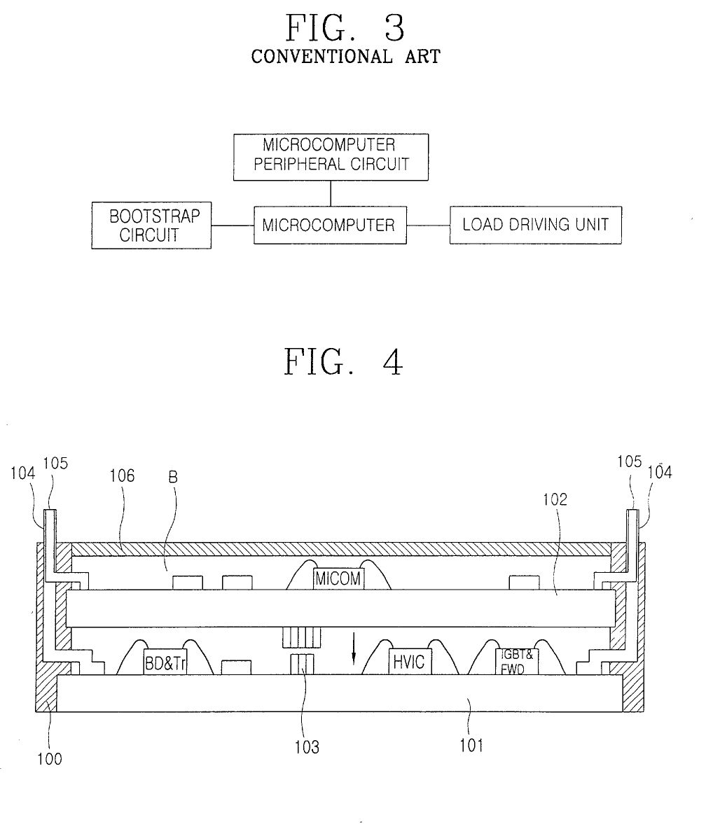

### DETAILED DESCRIPTION OF THE PREFERRED EMBODIMENTS

Reference will now be made in detail to the preferred embodiments of the present invention, examples of which are illustrated in the accompanying drawings

FIG. 4 shows a structure of one system module in accordance with the present invention.

As shown in the drawing, a groove is made at the lower side surface of the module body 100, to support a ceramic PCB 101, and a groove is made at the middle side surface, to support an epoxy PCB 102. A socket 103, having a less pins reduced in number, is disposed between the ceramic PCB 101 and the epoxy PCB 102

A power pin 104 for receiving a power signal from an external source is mounted at the upper portion of the ceramic PCB 101, so as to be connected with an external terminal.

Power elements (BD&Tr, HVIC, IGBT&FWD) are connected by wire bonding. A signal pin 105 for receiving various signals from an external source is mounted at the upper portion of the epoxy PCB 102, which is separated from the power pin 104.

A microcomputer device and its peripheral devices are mounted on the epoxy PCB by wire bonding.

The portion ‘B’ is coated with a heat-hardened resin in a gel state to protect the wire bonding in the internal PCB 101 and 102 of the module body and elements, and a cover 106 covers the entire module.

The operation and effect of the one system module constructed as described will now be explained in detail.

First, a groove is made at the lower portion of the side face of the module body 100 and a ceramic PCB 101 is inserted into the groove so as to be supported, and a groove is made at the middle side surface of the module body 100 and the epoxy PCB 102 is inserted into the groove so as to be supported.

The module body 100 is a case made of a hard molding heat-hardened resin.

Resultantly, the PCBs are constructed in a two-story structure.

On the lower PCB, largely, heating components, such as a bridge diode, a power transistor, a power element, a freewheeling diode (BD&Tr, IGBT, FWD) and a high-voltage IC (HVIC), are mounted.

In order to release heat of the heating element, a ceramic PCB 101 having an excellent heat transfer characteristic is used. Since the ceramic PCB 101 has a superior heat transfer characteristic to that of other PCBs, it has a favorable heat release effect.

Connected with the ceramic PCB 101, the socket 103 serves to electrically connect the ceramic PCB 101 and the upper PCB 102.

Components, such as microcomputer, its peripheral circuits, a valve driving circuit in case of a washing machine or a sensing circuit for sensing the state of a motor, irrespective of heat are mounted on the upper PCB, the epoxy PCB 102

In this manner, constructed module is used to drive a motor by means of an inverter, it needs to be integrated and small-sized. Since the microcomputer is mounted on the PCB in a bare state, it is connected by gold wire bonding.

Wire bonding is also performed on the ceramic PCB 101, a lower PCB. In this case, an aluminum wire bonding is performed.

Signal flows in the one system module constructed as described above are as follows.

When power (AC 220V) is applied, the microcomputer mounted on the epoxy PCB 102 is in a standby state. When the microcomputer generates a command, the command is transmitted through the socket 103 to the high voltage IC (HVIC) mounted on the ceramic PCB 102.

Upon receipt of the command, the HVIC drives the power element (IGBT) to drive a motor (not shown).

Conventionally, the power pin and the signal pin for receiving a power signal and various signals from an external source are mounted on the ceramic PCB 101 Compared to this, in the present invention, the power pin and the signal pin is separately disposed to thereby prevent pins from gathering together at one side which leads to a difficulty in fabricating an instrument.

A power pin 104 as a power board is mounted on the ceramic PCB 101 by soldering, and a signal pin 105 as a signal board is mounted on the epoxy PCB 102 by soldering.

In this manner, the power pin 104 and the signal pin 105 are separately disposed, so that when the module is applied, its pattern can be easily fabricated. In addition, by reducing the pins in number of the socket 103, the load applied to the socket is reduced, so that even if vibration occurs frequently (i.e., a washing machine), the PCB can be firmly supported.

When the power pin 104 and the signal pin 105 are completely mounted, in order to protect the wire bonding for mounting the components on the lower and the upper PCBs 101 and 102 of the module body 100 and the components mounted thereon by wire bonding, the portion ‘B’ is coated with a heat-hardened resin in a gel state and its upper portion is covered by the cover 106.

The cover 106 is formed to precisely fit the structure of the module.

As so far described, according to the one system module of the present invention, the ceramic PCB and the epoxy PCB can be firmly supported by the groove made on the module body. And, since the power pin and the signal pin are separately disposed on the two PCBs, the pins of the socket are reduced in number, so that the area utilization of the PCB is heightened as well as acquiring a compact module.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the meets and bounds of the claims, or equivalence of such meets and bounds are therefore intended to be embraced by the appended claims.

What is claimed is:

1. A one system module in which a socket is placed between a ceramic PCB and an epoxy PCB that are disposed inside a module body, a power element and signal elements are respectively mounted on the upper portion of each PCB, wherein a groove is made at the lower side surface and at the middle side surface of the module body to support the ceramic PCB and the epoxy PCB formed in two-story structure, and a power pin for receiving a power signal from an external source is mounted on the ceramic PCB and a signal pin for receiving various signals from an external source is mounted on the epoxy PCB

2. The one system module according to claim 1, wherein aluminum wire bonding is performed to mount elements on the ceramic PCB, while gold wire bonding is performed to mount a microcomputer on the epoxy PCB.

3. The one system module according to claim 1, wherein the power pin as a power board is mounted on the ceramic PCB by soldering, while the signal pin as a signal board is mounted on the epoxy PCB by soldering.

4. The one system module according to claim 1, wherein the power pin is mounted on the ceramic PCB while the signal pin is mounted on the epoxy PCB, thereby reducing the pins in number of the socket.
